(19) United States
(12) Patent Application Publication
(10) Pub. No.: US 2026/0245648 A1
(43) Pub. Date: Aug. 20, 2026

(54) ADJUSTING READ VOLTAGE OFFSETS IN MEMORY SYSTEMS

(71) Applicant: Micron Technology, Inc., Boise, ID (US)

(72) Inventors: Nicola Ciocchini, Boise, ID (US); Ugo Russo, Boise, ID (US); Patrick R. Khayat, San Diego, CA (US); Mustafa N. Kaynak, San Diego, CA (US); Sivagnanam Parthasarathy, Carlsbad, CA (US)

(21) Appl. No.: 19/535,888

(22) Filed: Feb. 10, 2026

Related U.S. Application Data
(60) Provisional application No. 63/759,985, filed on Feb. 18, 2025.

(51) Int. Cl. G11C 29/42; G11C 11/4096; G11C 29/44

(52) U.S. Cl. CPC G11C 29/42; G11C 11/4096; G11C 29/44

(57) ABSTRACT

Methods, systems, and devices for adjusting read voltage offsets in memory systems are described. A memory system may support a feed-forward process, and may perform a first read with a first offset and store a first quantity of errors, perform a second read with a second offset and store a second quantity of errors, and determine an offset to apply to a future read based on whether the first quantity of errors is lower than the second quantity of errors, or vice versa. A next offset or adjusted read voltage may in some cases be used for a sequential read, or may be stored and used in random reads. In some examples, the memory system may proactively perform read error handling (REH). The memory system may also perform a valley track process to determine, or estimate, an offset to a target read voltage.

### CROSS REFERENCE

The present Application for Patent claims priority to U.S. Patent Application No. 63/759,985 by Ciocchini et al., entitled “ADJUSTING READ VOLTAGE OFFSETS IN MEMORY SYSTEMS,” filed Feb. 18, 2025, which is assigned to the assignee hereof, and which is expressly incorporated by reference in its entirety herein.

### TECHNICAL FIELD

The following relates to one or more systems for memory, including adjusting read voltage offsets in memory systems.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports adjusting read voltage offsets in memory systems in accordance with examples as disclosed herein.

FIG. 2 shows an example of a flow diagram that supports adjusting read voltage offsets in memory systems in accordance with examples as disclosed herein.

FIG. 3 shows an example of a voltage distribution that supports adjusting read voltage offsets in memory systems in accordance with examples as disclosed herein.

FIG. 4 shows an example block diagram of a memory system that supports adjusting read voltage offsets in memory systems in accordance with examples as disclosed herein.

FIGS. 5 and 6 show example flowcharts illustrating a method or methods that support adjusting read voltage offsets in memory systems in accordance with examples as disclosed herein.

### DETAILED DESCRIPTION

A memory system may support storing bits to memory cells according to different storage densities. For example, a memory system may support single-level cell (SLC) write operations to store a bit (e.g., a single bit) of information using one of two logic levels (e.g., 0 or 1), multi-level cell (MLC) write operations to store two bits of information, triple-level cell (TLC) operations for storing three bits of information, or quad-level cell (QLC) operations for storing four bits of information, and so on. In some examples, a read window budget (RWB) for the memory cells may represent a window between edges of two voltage distributions of different logic states within which a codeword may be accurately decoded. Some memory systems may experience RWB loss (e.g., reduction) due to incorrect placement of read voltages (e.g., read levels) during read operations, where the incorrect placement may be referred to as read position loss (RPL) in some examples. As RWB may impact read performance, some systems may implement corrective operations, including read error handling (REH), however, such corrective actions may increase a latency in operations. Further, RWB may degrade due to process variability and cell-to-cell crosstalk (e.g., coupling between physically approximate cells), further degrading throughput while increasing latency.

According to techniques described herein, a memory system may implement one or more processes to reduce RPL to improve system performance. For example, a memory system may support a feed-forward process, and may perform a first read with a positive offset and store a first bit error count (BEC), perform a second read with a negative offset and store a second BEC, and determine whether to apply a positive or negative offset to a future read operations based on whether the first BEC is different from (e.g., lower than, higher than) the second BEC. An adjusted read voltage may be used for a sequential read in some examples, or may be stored and used during random read operations in some examples. In some examples, if a BEC satisfies (e.g., is greater than, is greater than or equal to) a threshold BEC, the memory system may proactively perform REH as part of a feed-forward process to reduce or otherwise mitigate an error count. Additionally, or alternatively, in some examples, if a BEC of a first read satisfies a different threshold, the memory system may perform a valley track process to determine, or estimate, an offset to a target read voltage, and may apply a corresponding offset to a subsequent read operation.

Using a feed-forward process by applying one or more different offsets to a read voltage may reduce RPL and subsequently reducing decoding latency of a memory system while increasing throughput. Further, the feed-forward process may consequently reduce REH-related latency by reducing a trigger rate of REH, while avoiding added latency by implementing each offset during a subsequent read operation. Additionally, or alternatively, applying a same offset that results in successful decoding of a current or previous read operation to a sequential read or random read operation may also increase the memory system's overall performance. Proactively performing REH may also expedite correction of RPL, reducing time and latency associated with decoding and error correction at larger RPL values. Further, applying a valley track process may provide a relatively quick and low-latency operation for RPL correction and performance improvement, for example, by correcting RPL in the presence of relatively high BECs using two reads and a slope calculation.

In addition to applicability in memory systems as described herein, techniques for adjusting read voltage offsets in memory systems may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by using a feed-forward process to reduce RPL, which may decrease processing or latency times, improve response times and throughput, or otherwise improve user experience and performance, among other benefits. Further, proactively performing REH for relatively high BECs may further decrease processing time and latency during decoding, while implementing a valley track process may similarly improve performance related to reduced RPL.

Features of the disclosure are illustrated and described in the context of systems, devices, and circuits. Features of the disclosure are further illustrated and described in the context of flow diagrams, voltage distributions, and flowcharts.

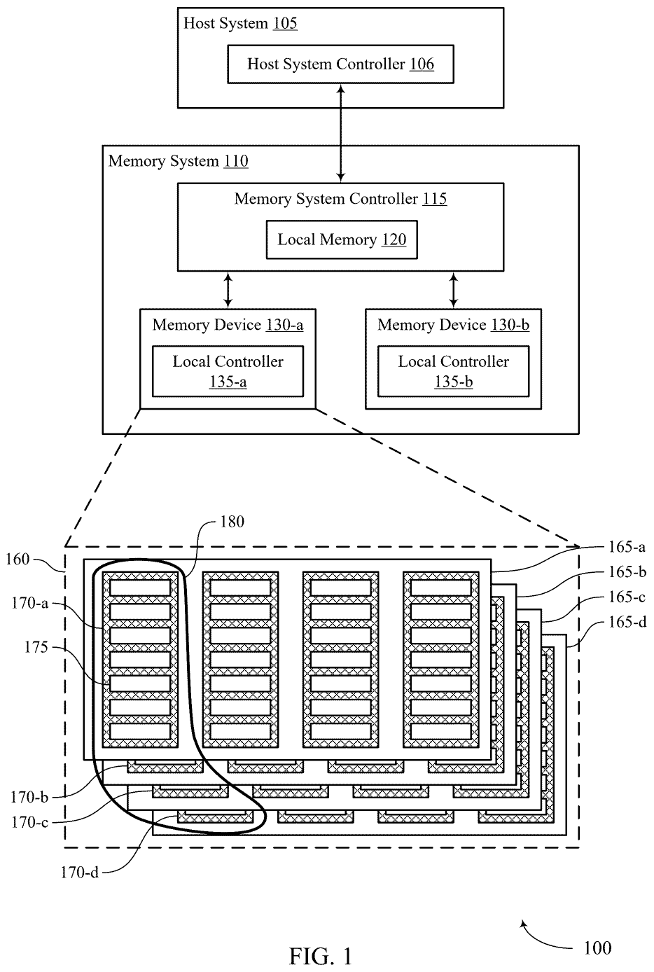

FIG. 1 shows an example of a system 100 that supports adjusting read voltage offsets in memory systems in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as SLCs. Additionally, or alternatively, a NAND memory device 130 may include memory cells configured to each store multiple bits of information, which may be referred to as MLCs if configured to each store two bits of information, as TLCs if configured to each store three bits of information, as QLCs if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0 ” of plane 165-a, block 170-b may be “block 0 ” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

Techniques described herein may support one or more processes to reduce RPL to improve system performance. For example, the memory system 110 (or one or more devices of the memory system 110) support a feed-forward process, and may perform a first read with a positive offset and store a first BEC, perform a second read with a negative offset and store a second BEC, and determine whether to apply a positive or negative offset to a future read based on whether the first BEC is lower than the second BEC, or vice versa. A subsequent offset or adjusted read voltage may be used for a sequential read, or may be stored and used in random reads. In some examples, if a BEC satisfies (e.g., is greater than, is greater than or equal to) a threshold BEC, the memory system 110 may proactively perform REH as part of a feed-forward process to reduce an error count. Additionally, or alternatively, if a BEC of a first read satisfies a different threshold, the memory system 110 may perform a valley track process to determine, or estimate, an offset to a target read voltage, and may apply a corresponding offset to a following read.

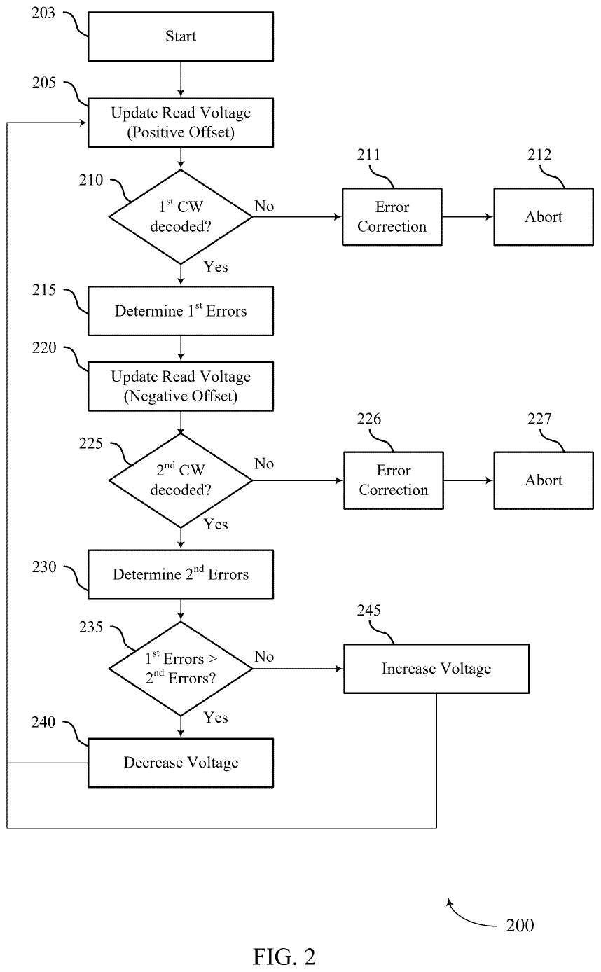

FIG. 2 shows an example of a flow diagram 200 that supports adjusting read voltage offsets in memory systems in accordance with examples as disclosed herein. One or more aspects of the flow diagram 200 of FIG. 2 may implement or may be implemented by one or more aspects of the system 100. For example, the flow diagram 200 may illustrate communication and operations performed at a memory system, such as the memory system 110 described in FIG. 1. In some examples, the flow diagram 200 illustrate one or more processes, including a feed-forward process, for reducing RPL, among other operations for improving performance.

In some examples, the memory system may be an example of a NAND system including one or more arrays of memory cells configured as SLCs, MLCs, TLCs, QLCs, or any combination of memory cell types. For example, the one or more arrays may include memory cells configured as TLCs configured to store one of eight logic states. In some examples, a read operation may lose a percentage of a total available RWB (e.g., an intrinsic RWB) due to RPL. For example, RPL may cause a read voltage to be off-center from a target read voltage that is centered between two adjacent voltage distributions. The off-center placement may reduce a window for successful decoding, increasing BECs as well as a frequency of non-decodable reads (e.g., a quantity of reads performed outside of the RWB). RPL in some examples may be a result of variabilities between memory system components, including block to block variability, within block variability, die to die variability, and program to read delay variability. Additional factors may include line drift as well as a cadence (e.g., periodicity) of various operations (e.g., cadence, or periodicity, of block family error avoidance (BFEA) scans for storage charge loss, which may change per block based on relative storage charge loss associated with that block).

The memory system may perform corrective operations in the case of a failed read of a codeword. For example, the memory system may perform REH, which may involve calculating the target read voltage as well as using one or more soft bits to enable improved low-density parity-check (LDPC) decoding. REH may, however, increase a latency of operations. RWB available for a default read may impact read performance, and one or more latency targets may affect the usage of REH and valley track capability of the memory system (e.g., may allow a relatively low trigger rate of REH). RPL may thus reduce read performance in the memory system by increasing latency and decreasing throughput, or by increasing a quantity of errors due to decreased REH. Performance may also decrease further as intrinsic RWB is degraded due to impact of process variability, or due to cell-to-cell crosstalk (e.g., threshold voltages of memory cells affecting threshold voltages of nearby memory cells within a relative physical proximity), among other factors. Cell-to-cell cross talk may also increase with cell density.

In some examples, the memory system may support one or more processes to reduce RPL. For example, the memory system may support a feed-back process (e.g., a “sticky read”) to determine an improved read offset from a successful REH event, and may use the offset for subsequent pages in a sequential read. Additionally, or alternatively, the memory system may implement a block family error avoidance (BFEA) process to mitigate the impact of program to read delay difference from block to block. For example, NAND components may be subject to storage charge loss (SCL) after programming, which may cause RWB loss and threshold voltage reduction, reducing or limiting read performance of NAND-based systems. To mitigate SCL effects, the memory system may proactively track SCL by system or NAND component using a BFEA scan, which may involve assigning each block of one or more blocks to a respective bin according to a measured SCL, where each bin may include a grouping of blocks with substantially similar elapsed times since programming, and an associated offset.

Some BFEA processes may involve performing BFEA according to relatively small granularities, including per word line group (WGR) and program/erase cycle (PEC) cluster. For example, the memory system may determine a set of read trim offsets (e.g., from Level 1 to Level 7) for a lowest page read bit error rate (RBER), among a defined set of offsets stored in one or more firmware tables. The memory system may label read offsets (e.g., with a number from 0 to 7) and store the read offsets in firmware tables for each block or block family. In some cases, an adaptive BFEA process may support a feed-back process to learn read offsets from successful REH events, and save the read offsets to BFEA tables to support both sequential and random reads. However, in some examples, adaptive BFEA may involve additional learning phases to improve performance as well as operations to determine one or more parameters. Further, a feed-back functionality for some operations (e.g., normal sticky read operations) may lack persistence for read offsets across blocks or power cycles (e.g., invalid for random reads), while static tables for non-adaptive BFEA may lack an ability to respond to die to die variability and line drift.

As described herein, the memory system may support a feed-forward process to further reduce RPL, for example, by leveraging ECC statistics to perform on the fly valley tracking. For example, the process illustrated in FIG. 2 may leverage a quantity of corrected bits, or a BEC, by a decoder (e.g., to build a valley histogram). The process may begin at 203.

In some examples, at each read in a sequential read sequence using the process, the memory system may apply an offset (e.g., rd_offset_ECC) to a default read (e.g., using a prefix). For example, at 205, the memory system may update a read voltage. In some examples, the memory system may apply, in accordance with a read operation, a first read voltage to a first page of memory cells, where the first read voltage may be in accordance with a first offset (e.g., a positive offset of rd_offset_ECC, where rdx=default+rd_offset_ECC) applied to a read voltage (e.g., to a default read voltage affected by RPL). In some cases, the memory system may apply the first offset to the read voltage before applying the first read voltage to the first page, and applying the first offset may include increasing the read voltage by a value (e.g., a predefined value, a voltage value).

At 210, the memory system may attempt to read and decode a first codeword (e.g., CW0) associated with the first page, where determining a first quantity of bit errors is in accordance with decoding the first codeword. For example, if the decoding is successful, the memory system may determine a first quantity of bit errors, or a first BEC (e.g., BEC0), that may be associated with the first page of memory cells. In some cases, the quantity of errors may be an available statistic based on successfully decoding the first codeword. In some examples, the memory system may proceed to 215 and store the first quantity of bit errors.

If the memory system fails to decode the first codeword, the memory system may refrain from determining the first quantity of bit errors (e.g., no BEC statistic may be provided based on a failed decoding). In some cases, if any codeword is not decodable, the process described with reference to FIG. 2 may be aborted as no error or BEC information may be available. For example, the memory system may proceed to 211 to correct one or more errors associated with the first page in accordance with being unable to decode the first codeword, and may proceed to 212 to abort additional operations for the feed-forward process. In some cases, the memory system may perform REH as described herein at 211 after the failed decoding, or after multiple failed decoding operations (e.g., a threshold quantity of failed decoded codewords).

At 220, the memory system may update the read voltage a second time. For example, the memory system may apply, in accordance with the read operation, a second read voltage to a second page of memory cells in accordance with applying the first read voltage, where the second read voltage may be in accordance with a second offset (e.g., a negative offset of rd_offset_ECC, where rdx=default−rd_offset_ECC) applied to the read voltage. The memory system may apply the second offset to the read voltage before applying the second read voltage to the second page, and applying the second offset may include decreasing the read voltage by the voltage value, or by another voltage value.

At 225, the memory system may attempt to read and decode a second codeword (e.g., CW1) associated with the second page, where determining a second quantity of bit errors may be in accordance with decoding the second codeword. For example, if the decoding is successful, the memory system may determine a second quantity of bit errors, or a second BEC (e.g., BEC1), that may be associated with the second page of memory cells. The memory system may proceed to 230 and store the second quantity of bit errors. If the decoding is unsuccessful, the memory system may proceed to 226 to correct one or more errors (e.g., to perform REH), and may abort one or more operations at 227.

In some examples, the memory system may adjust the read voltage based on the first quantity of bit errors being different from the second quantity of bit errors. For example, at 235, the memory system may compare the first quantity of bit errors (or BEC0) to the second quantity of bit errors (or BEC1) after storing the respective quantities of bit errors (e.g., at 225). In some examples, the memory system may determine that the first quantity is greater than the second quantity (e.g., BEC0>BEC1), and may proceed to 240, where adjusting the read voltage may include decreasing the read voltage. For example, if BEC0>BEC1, a negative offset may result in improved performance (or vice versa). Additionally, or alternatively, the memory system may determine that the first quantity is less than the second quantity (e.g., BEC0<BEC1), and may proceed to 245, where adjusting the read voltage may include increasing the read voltage. Adjusting the read voltage may in some cases include increasing or decreasing the read voltage by a defined offset (e.g., an offset LDPC_corr, where rdx=rdx+LDPC_corr, or rdx=rdx−LDPC_corr). The defined offset (e.g., LDPC_corr) may be the same as, or different from, the offsets applied at 205 and 220 (e.g., as rd_offset_ECC). Additionally, or alternatively, the memory system may determine that the first quantity of bit errors is equal to the second quantity of bit errors (e.g., BEC0=BEC1), and may refrain from adjusting the read voltage.

In some examples, the memory system may repeat the operations in FIG. 2 for each level (e.g., each logic state) in each page type (e.g., upper, middle, lower pages for TLC) during a sequential read. Further, the first offset, second offset, and the defined offset by which the read voltage is adjusted may be examples of defined parameters at the memory system (e.g., rd_offset_ECC, LPDC_corr, or both, may be mConfig parameters). Additionally, or alternatively, the offsets may be dynamic and indicated by a host system (e.g., the host system 105 described in FIG. 1) or calculated on the fly. In some examples, the memory system may perform the operations in FIG. 2 based on receiving a command for reading data from a block of memory cells, where the block may include at least the first page and the second page.

In some examples, the memory system may refrain from performing one or more operations if a BEC is relatively low. For example, the memory system may determine that a quantity of bit errors (e.g., a maximum of BEC0 and BEC1) does not satisfy a threshold value (e.g., BEC_th_low), and may refrain from adjusting the read voltage for one or more blocks. In some cases, the memory system may refrain from one or more operations for one or more blocks or pages, or for a duration of time, or until indicated by a host system. In some cases, when the errors are below the threshold (e.g., <BEC_th_low, where BEC_th_low=ECC_cap/10), a read voltage may be centered correctly, and the memory system may omit the process to correct the offset.

In some examples, the memory system may support non-adaptive BFEA, and may apply the adjusted read voltage to a third page of memory cells in accordance with adjusting the read voltage, where the read operation may include a sequential read operation (e.g., the memory system may use a read offset for a next page). The memory system may, in some cases, store the value for adjustment (e.g., store LPDC_corr as a positive or negative offset, or store the adjusted voltage) for use in a sequential read (e.g., a sticky read). Additionally, or alternatively, the memory system may support adaptive BFEA. For adaptive BFEA, the memory system may support sequential reads as well as random reads. For a random read, the memory system may store an indication of the adjustment made to the read voltage (e.g., LPDC_corr as a positive or negative offset, or store the adjusted voltage) in accordance with adjusting the read voltage (e.g., may update BFEA tables), and may apply, in accordance with a random read operation, the adjusted read voltage to a page of memory cells. In some examples, the memory system may implement BFEA, and after a threshold (e.g., a threshold BEC, RBER, or other parameter) is satisfied for one or more bins, may perform one or more processes described herein with respect to FIG. 2.

In some examples, the memory system may support proactive REH operations. For example, some memory systems may perform REH after a single failure, or after a quantity of failures (e.g., at 211 or 226), as described herein. However, a read voltage may be within a region where decoding may be possible, but with a relatively high latency for decoding (e.g., relatively close to an edge of an RWB). The memory system may experience a relatively high BEC in such a region, and the resulting decoding latency may last for a substantial duration of time for relatively low REH trigger rates. In some examples, to mitigate falling within similar regions, the memory system may perform a feed-forward process involving proactive REH performance if a BEC is above a threshold BEC. In some cases, such a feed-forward process may be different from feed-back processes (e.g., sticky reads) that use REH as a feedback mechanism for read level adjustment.

In some examples, adjusting offsets using a feed-forward process as described herein may leverage a decoder output (e.g., LDPC decoder output) to perform valley tracking without adding extra reads and latency (e.g., may be latency neutral), improving performance compared to feed-back solutions (e.g., sticky read) that, while maintaining some throughput performance, may incur added REH latency and some degraded throughput due to higher LDPC latency. Further, performing proactive REH may mitigate latency and performance decrease from cases where RBER (or BEC) is too low to cause hard LDCP decoding failures, but high enough to cause increases in LDPC latency.

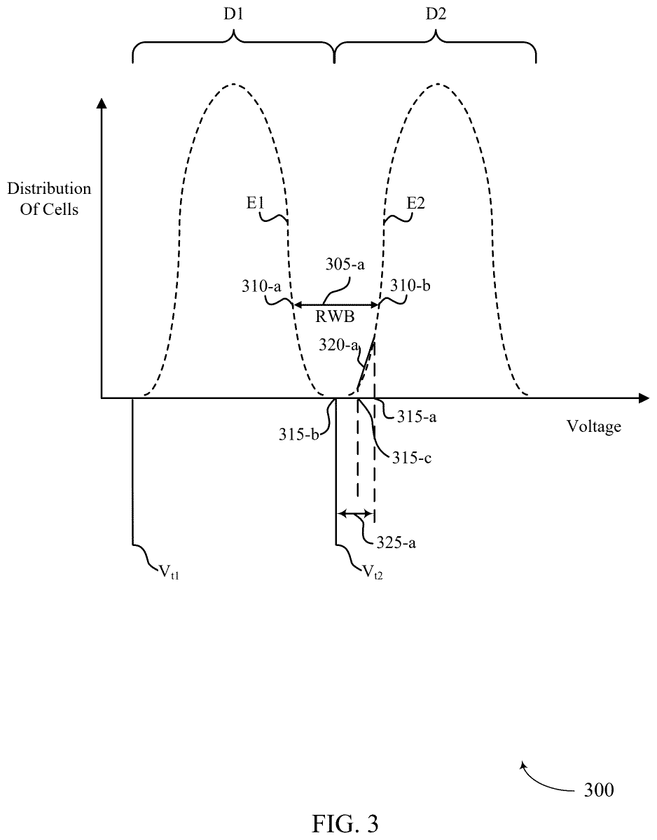

FIG. 3 shows an example of a voltage distribution 300 that supports adjusting read voltage offsets in memory systems in accordance with examples as disclosed herein. One or more aspects of the voltage distribution 300 of FIG. 3 may implement or may be implemented by one or more aspects of the system 100 and the flow diagram 200. For example, the voltage distribution 300 may illustrate a voltage distribution for memory cells of a memory system, such as the memory system 110 described in FIG. 1, which may support adjusting read voltage offsets as described herein. In some examples, the voltage distribution 300 may illustrate implementation of a valley track process as described herein.

For example, the voltage distribution 300 may include a distribution D1 corresponding to a first logic state and a distribution D2 corresponding to a second logic state. Each distribution may illustrate a distribution of memory cells (e.g., an actual distribution, a potential distribution, an average distribution) that may store various voltages associated with respective logic states after programming. In some cases, the distributions D1 and D2 may represent two logic states and two TLC distributions of 8 total distributions, among other memory cell type distributions. Each distribution may also include a threshold voltage, such as threshold voltages Vₜ₁ and Vₜ₂, which may each represent a respective target read voltage for reading a respective logic state. The memory system may also include an RWB 305-a, which may represent a range of voltages between a point 310-a on an edge E1 of the distribution D1, and a point 310-b on an edge E2 of the distribution D2. In some cases, the points 310-a and 310-b may correspond to read voltages (or quantities of flipped bits due to errors, or BECs) at or past which codewords may be uncorrectable.

In some examples, the operations described in FIG. 2 (e.g., an entire dithering sequence to collect BEC0 and BEC1) may be replaced by an internal command (e.g., a valley track command, pARC lite in B78R), which may be issued when BEC from decoding (e.g., LDPC decoding) satisfies (e.g., is above) a threshold (e.g., a threshold BEC_th for performing the valley track process), and the resulting read offset may be used for a next page (e.g., feed-forwarded in the same way as described herein with respect to FIG. 2).

For example, a memory system may implement a valley track process to determine an offset 325-a between a read voltage 315-a (e.g., a current, first read voltage affected by RPL) and a read voltage 315-b (e.g., a target read voltage, an estimated target read voltage) corresponding to the threshold voltage Vₜ₂ for the RWB 305-a. In some examples, the memory system may apply, in accordance with a read operation, the read voltage 315-a to a first page of memory cells, and may issue an internal command (e.g., valley track command) in response to a first quantity of bit errors resulting from the first page (e.g., a first BEC) satisfying a threshold value. The memory system may also apply a read voltage 315-c (e.g., a second read voltage) to the first page of memory cells that may result in a second quantity of bit errors (or a second BEC). In some cases, the memory system may determine that the first quantity of bit errors satisfies the threshold value based on applying the first read voltage and the second read voltage.

The memory system may calculate a slope 320-a (e.g., in accordance with issuing the command) associated with the first quantity of bit errors and the second quantity of bit errors, and may adjust the read voltage based on the slope. For example, the memory system may estimate the read voltage 315-b using the slope. The memory system may read a second page of memory cells using the adjusted read voltage based on the offset 325-a between the read voltage 315-a and the read voltage 315-b. The first page and the second page may further be sequential pages of a block of memory cells. In some cases, implementing a valley track process may improve RWB and reduce latency while increasing throughput by performing a relatively small quantity of operations to adjust a read voltage to an estimated read voltage that may be close to or match a target read voltage.

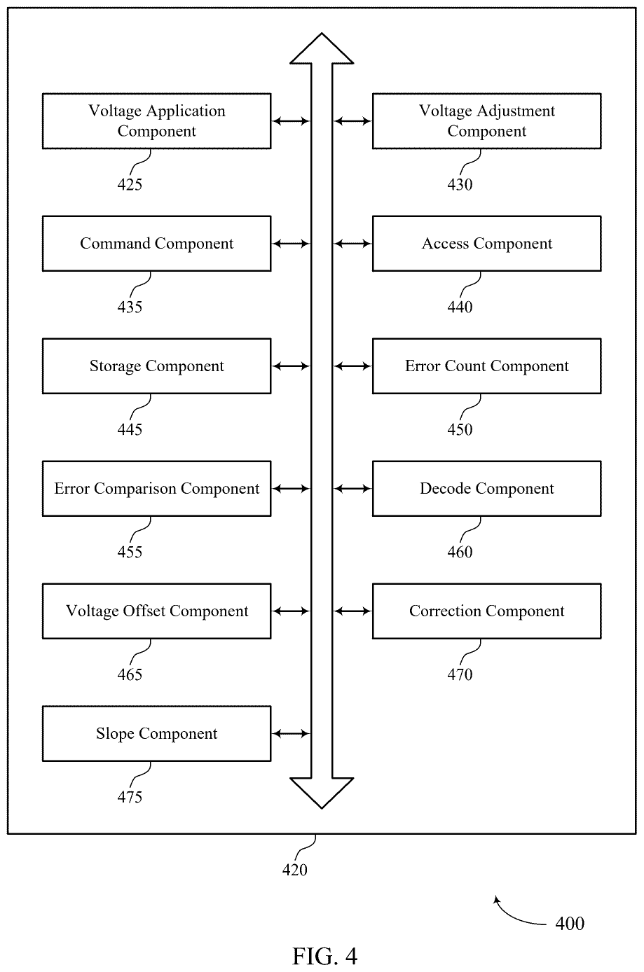

FIG. 4 shows a block diagram 400 of a memory system 420 that supports adjusting read voltage offsets in memory systems in accordance with examples as disclosed herein. The memory system 420 may be an example of aspects of a memory system as described with reference to FIGS. 1 through 3. The memory system 420, or various components thereof, may be an example of means for performing various aspects of adjusting read voltage offsets in memory systems as described herein. For example, the memory system 420 may include a voltage application component 425, a voltage adjustment component 430, a command component 435, an access component 440, a storage component 445, an error count component 450, an error comparison component 455, a decode component 460, a voltage offset component 465, a correction component 470, a slope component 475, or any combination thereof. Each of these components, or components of subcomponents thereof (e.g., one or more processors, one or more memories), may communicate, directly or indirectly, with one another (e.g., via one or more buses).

The voltage application component 425 may be configured as or otherwise support a means for applying, in accordance with a read operation, a first read voltage to a first page of memory cells, where the first read voltage is in accordance with a first offset applied to a read voltage. In some examples, the voltage application component 425 may be configured as or otherwise support a means for applying, in accordance with the read operation, a second read voltage to a second page of memory cells in accordance with applying the first read voltage, where the second read voltage is in accordance with a second offset applied to the read voltage. The voltage adjustment component 430 may be configured as or otherwise support a means for adjusting the read voltage based on a first quantity of bit errors associated with the first page of memory cells being different from a second quantity of bit errors associated with the second page of memory cells.

In some examples, the voltage application component 425 may be configured as or otherwise support a means for applying the adjusted read voltage to a third page of memory cells in accordance with adjusting the read voltage, where the read operation includes a sequential read operation.

In some examples, the storage component 445 may be configured as or otherwise support a means for storing an indication of the adjustment made to the read voltage in accordance with adjusting the read voltage. In some examples, the voltage application component 425 may be configured as or otherwise support a means for applying, in accordance with a random read operation, the adjusted read voltage to a fourth page of memory cells in accordance with storing the indication of the adjustment made to the read voltage.

In some examples, the error count component 450 may be configured as or otherwise support a means for determining the first quantity of bit errors associated with the first page of memory cells and the second quantity of bit errors associated with the second page of memory cells. In some examples, the storage component 445 may be configured as or otherwise support a means for storing the first quantity of bit errors and the second quantity of bit errors to the memory system after determining the first quantity of bit errors and the second quantity of bit errors. In some examples, the error comparison component 455 may be configured as or otherwise support a means for comparing the first quantity of bit errors to the second quantity of bit errors after storing the second quantity of bit errors to the memory system, where adjusting the read voltage is based on comparing the first quantity of bit errors to the second quantity of bit errors.

In some examples, the error comparison component 455 may be configured as or otherwise support a means for determining that the first quantity of bit errors is greater than the second quantity of bit errors, where adjusting the read voltage includes increasing the read voltage based on the first quantity of bit errors being greater than the second quantity of bit errors.

In some examples, the error comparison component 455 may be configured as or otherwise support a means for determining that the first quantity of bit errors is less than the second quantity of bit errors, where adjusting the read voltage includes decreasing the read voltage based on the first quantity of bit errors being less than the second quantity of bit errors.

In some examples, the error comparison component 455 may be configured as or otherwise support a means for determining that the first quantity of bit errors is equal to the second quantity of bit errors. In some examples, the voltage adjustment component 430 may be configured as or otherwise support a means for refraining from adjusting the read voltage based on the first quantity of bit errors being equal to the second quantity of bit errors.

In some examples, the decode component 460 may be configured as or otherwise support a means for decoding a first codeword associated with the first page, where determining the first quantity of bit errors is in accordance with decoding the first codeword. In some examples, the decode component 460 may be configured as or otherwise support a means for decoding a second codeword associated with the second page, where determining the second quantity of bit errors is in accordance with decoding the second codeword.

In some examples, the voltage application component 425 may be configured as or otherwise support a means for applying the first read voltage to a fifth page of a second block of memory cells. In some examples, the error comparison component 455 may be configured as or otherwise support a means for determining that a third quantity of bit errors associated with the fifth page does not satisfy a threshold value. In some examples, the voltage adjustment component 430 may be configured as or otherwise support a means for refraining from adjusting the read voltage for the second block based on determining that the third quantity of bit errors does not satisfy the threshold value.

In some examples, the command component 435 may be configured as or otherwise support a means for receiving a command for reading data from a block of memory cells, the block including at least the first page and the second page, where applying the first read voltage and applying the second read voltage is based on receiving the command.

In some examples, the voltage offset component 465 may be configured as or otherwise support a means for applying the first offset to the read voltage before applying the first read voltage to the first page of memory cells, where applying the first offset to the read voltage includes increasing the read voltage by a voltage value. In some examples, the voltage offset component 465 may be configured as or otherwise support a means for applying the second offset to the read voltage before applying the second read voltage to the second page of memory cells, where applying the second offset to the read voltage includes decreasing the read voltage by the voltage value.

In some examples, the command component 435 may be configured as or otherwise support a means for receiving a command for reading second data from a third block of memory cells, the third block including at least a sixth page. In some examples, the error count component 450 may be configured as or otherwise support a means for refraining from determining a fourth quantity of bit errors associated with the sixth page based on being unable to decode a third codeword associated with the sixth page.

In some examples, the correction component 470 may be configured as or otherwise support a means for correcting one or more errors associated with the sixth page in accordance with being unable to decode the third codeword associated with the sixth page.

In some examples, the voltage application component 425 may be configured as or otherwise support a means for applying, in accordance with a read operation, a first read voltage to a first page of memory cells. The command component 435 may be configured as or otherwise support a means for issuing an internal command in response to a first quantity of bit errors associated with the first page of memory cells satisfying a threshold value. The access component 440 may be configured as or otherwise support a means for reading a second page of memory cells using an adjusted read voltage that is based on issuing the internal command and based on an offset between the first read voltage and a target read voltage.

In some examples, applying the first read voltage to the first page of memory cells results in the first quantity of bit errors, and the voltage application component 425 may be configured as or otherwise support a means for applying a second read voltage to the first page of memory cells, where applying the second read voltage to the first page of memory cells results in a second quantity of bit errors. In some examples, the error comparison component 455 may be configured as or otherwise support a means for determining that the first quantity of bit errors satisfies the threshold value based on applying the first read voltage and the second read voltage.

In some examples, the slope component 475 may be configured as or otherwise support a means for calculating a slope associated with the first quantity of bit errors and the second quantity of bit errors, where the adjustment to the read voltage is based on calculating the slope.

In some examples, the first page and the second page are sequential pages of a block of memory cells.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

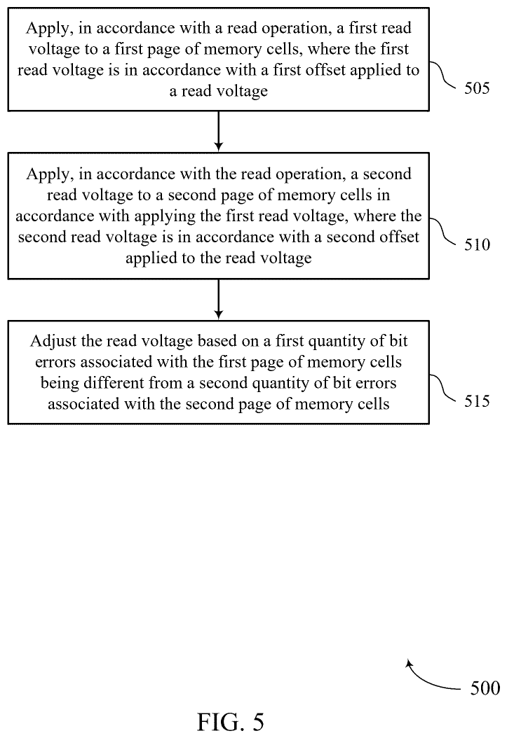

FIG. 5 shows a flowchart illustrating a method 500 that supports adjusting read voltage offsets in memory systems in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include applying, in accordance with a read operation, a first read voltage (e.g., a first updated read voltage applied at 205) to a first page of memory cells (e.g., a page 175), where the first read voltage is in accordance with a first offset (e.g., +rd_offset_ECC) applied to a read voltage (e.g., a default read voltage). In some examples, aspects of the operations of 505 may be performed by a voltage application component 425 as described with reference to FIG. 4.

At 510, the method may include applying, in accordance with the read operation, a second read voltage (e.g., a second updated read voltage applied at 220) to a second page of memory cells (e.g., a page 175) in accordance with applying the first read voltage, where the second read voltage is in accordance with a second offset (−rd_offset_ECC) applied to the read voltage. In some examples, aspects of the operations of 510 may be performed by a voltage application component 425 as described with reference to FIG. 4.

At 515, the method may include adjusting the read voltage (e.g., decreasing the read voltage at 240, increasing the read voltage at 245) based on a first quantity of bit errors (e.g., BEC0) associated with the first page of memory cells being different from a second quantity of bit errors (e.g., BEC1) associated with the second page of memory cells. In some examples, aspects of the operations of 515 may be performed by a voltage adjustment component 430 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for applying, in accordance with a read operation, a first read voltage to a first page of memory cells, where the first read voltage is in accordance with a first offset applied to a read voltage; applying, in accordance with the read operation, a second read voltage to a second page of memory cells in accordance with applying the first read voltage, where the second read voltage is in accordance with a second offset applied to the read voltage; and adjusting the read voltage based on a first quantity of bit errors associated with the first page of memory cells being different from a second quantity of bit errors associated with the second page of memory cells.

Aspect 2: The method, apparatus, or non-transitory computer-readable medium of aspect 1, further including operations, features, circuitry, logic, means, or instructions, or any combination thereof for applying the adjusted read voltage to a third page of memory cells in accordance with adjusting the read voltage, where the read operation includes a sequential read operation.

Aspect 3: The method, apparatus, or non-transitory computer-readable medium of any of aspects 1 through 2, further including operations, features, circuitry, logic, means, or instructions, or any combination thereof for storing an indication of the adjustment made to the read voltage in accordance with adjusting the read voltage and applying, in accordance with a random read operation, the adjusted read voltage to a fourth page of memory cells in accordance with storing the indication of the adjustment made to the read voltage.

Aspect 4: The method, apparatus, or non-transitory computer-readable medium of any of aspects 1 through 3, further including operations, features, circuitry, logic, means, or instructions, or any combination thereof for determining the first quantity of bit errors associated with the first page of memory cells and the second quantity of bit errors associated with the second page of memory cells; storing the first quantity of bit errors and the second quantity of bit errors to the memory system after determining the first quantity of bit errors and the second quantity of bit errors; and comparing the first quantity of bit errors to the second quantity of bit errors after storing the second quantity of bit errors to the memory system, where adjusting the read voltage is based on comparing the first quantity of bit errors to the second quantity of bit errors.

Aspect 5: The method, apparatus, or non-transitory computer-readable medium of aspect 4, further including operations, features, circuitry, logic, means, or instructions, or any combination thereof for determining that the first quantity of bit errors is greater than the second quantity of bit errors, where adjusting the read voltage includes decreasing the read voltage based on the first quantity of bit errors being greater than the second quantity of bit errors.

Aspect 6: The method, apparatus, or non-transitory computer-readable medium of any of aspects 4 through 5, further including operations, features, circuitry, logic, means, or instructions, or any combination thereof for determining that the first quantity of bit errors is less than the second quantity of bit errors, where adjusting the read voltage includes increasing the read voltage based on the first quantity of bit errors being less than the second quantity of bit errors.

Aspect 7: The method, apparatus, or non-transitory computer-readable medium of any of aspects 4 through 6, further including operations, features, circuitry, logic, means, or instructions, or any combination thereof for determining that the first quantity of bit errors is equal to the second quantity of bit errors and refraining from adjusting the read voltage based on the first quantity of bit errors being equal to the second quantity of bit errors.

Aspect 8: The method, apparatus, or non-transitory computer-readable medium of any of aspects 4 through 7, further including operations, features, circuitry, logic, means, or instructions, or any combination thereof for decoding a first codeword associated with the first page, where determining the first quantity of bit errors is in accordance with decoding the first codeword and decoding a second codeword associated with the second page, where determining the second quantity of bit errors is in accordance with decoding the second codeword.

Aspect 9: The method, apparatus, or non-transitory computer-readable medium of any of aspects 1 through 8, further including operations, features, circuitry, logic, means, or instructions, or any combination thereof for applying the first read voltage to a fifth page of a second block of memory cells; determining that a third quantity of bit errors associated with the fifth page does not satisfy a threshold value; and refraining from adjusting the read voltage for the second block based on determining that the third quantity of bit errors does not satisfy the threshold value.

Aspect 10: The method, apparatus, or non-transitory computer-readable medium of any of aspects 1 through 9, further including operations, features, circuitry, logic, means, or instructions, or any combination thereof for receiving a command for reading data from a block of memory cells, the block including at least the first page and the second page, where applying the first read voltage and applying the second read voltage is based on receiving the command.

Aspect 11: The method, apparatus, or non-transitory computer-readable medium of aspect 10, further including operations, features, circuitry, logic, means, or instructions, or any combination thereof for applying the first offset to the read voltage before applying the first read voltage to the first page of memory cells, where applying the first offset to the read voltage includes increasing the read voltage by a voltage value and applying the second offset to the read voltage before applying the second read voltage to the second page of memory cells, where applying the second offset to the read voltage includes decreasing the read voltage by the voltage value.

Aspect 12: The method, apparatus, or non-transitory computer-readable medium of any of aspects 1 through 11, further including operations, features, circuitry, logic, means, or instructions, or any combination thereof for receiving a command for reading second data from a third block of memory cells, the third block including at least a sixth page and refraining from determining a fourth quantity of bit errors associated with the sixth page based on being unable to decode a third codeword associated with the sixth page.

Aspect 13: The method, apparatus, or non-transitory computer-readable medium of aspect 12, further including operations, features, circuitry, logic, means, or instructions, or any combination thereof for correcting one or more errors associated with the sixth page in accordance with being unable to decode the third codeword associated with the sixth page.

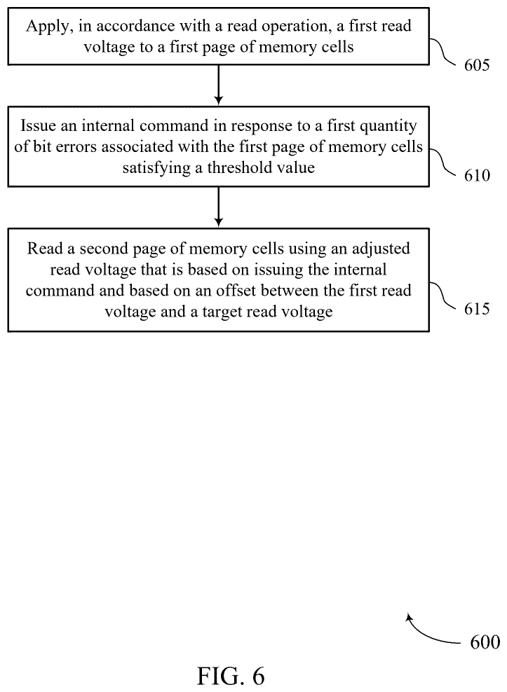

FIG. 6 shows a flowchart illustrating a method 600 that supports adjusting read voltage offsets in memory systems in accordance with examples as disclosed herein. The operations of method 600 may be implemented by a memory system or its components as described herein. For example, the operations of method 600 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 605, the method may include applying, in accordance with a read operation, a first read voltage (e.g., the read voltage 315-a) to a first page (e.g., a page 175) of memory cells. In some examples, aspects of the operations of 605 may be performed by a voltage application component 425 as described with reference to FIG. 4.

At 610, the method may include issuing an internal command (e.g., a valley track command issued by a memory system to estimate a target read voltage, such as the read voltage 315-b) in response to a first quantity of bit errors (e.g., a BEC) associated with the first page of memory cells satisfying a threshold value (e.g., a threshold BEC_th for performing the valley track process). In some examples, aspects of the operations of 610 may be performed by a command component 435 as described with reference to FIG. 4.

At 615, the method may include reading a second page of memory cells (e.g., a page 175) using an adjusted read voltage (e.g., a read voltage adjusted to an estimated voltage for the read voltage 315-b) that is based on issuing the internal command and based on an offset (e.g., the offset 325-a) between the first read voltage and a target read voltage (e.g., the read voltage 315-b). In some examples, aspects of the operations of 615 may be performed by an access component 440 as described with reference to FIG. 4.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 14: A method, apparatus, or non-transitory computer-readable medium including operations, features, circuitry, logic, means, or instructions, or any combination thereof for applying, in accordance with a read operation, a first read voltage to a first page of memory cells; issuing an internal command in response to a first quantity of bit errors associated with the first page of memory cells satisfying a threshold value; and reading a second page of memory cells using an adjusted read voltage that is based on issuing the internal command and based on an offset between the first read voltage and a target read voltage.

Aspect 15: The method, apparatus, or non-transitory computer-readable medium of aspect 14, where applying the first read voltage to the first page of memory cells results in the first quantity of bit errors, and the method, apparatuses, and non-transitory computer-readable medium further includes operations, features, circuitry, logic, means, or instructions, or any combination thereof for applying a second read voltage to the first page of memory cells, where applying the second read voltage to the first page of memory cells results in a second quantity of bit errors, and determining that the first quantity of bit errors satisfies the threshold value based on applying the first read voltage and the second read voltage.

Aspect 16: The method, apparatus, or non-transitory computer-readable medium of aspect 15, further including operations, features, circuitry, logic, means, or instructions, or any combination thereof for calculating a slope associated with the first quantity of bit errors and the second quantity of bit errors, where the adjustment to the read voltage is based on calculating the slope.

Aspect 17: The method, apparatus, or non-transitory computer-readable medium of any of aspects 14 through 16, where the first page and the second page are sequential pages of a block of memory cells.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

As used herein, the term “substantially” means that the modified characteristic (e.g., a verb or adjective modified by the term substantially) need not be absolute but is close enough to achieve the advantages of the characteristic.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
apply, in accordance with a read operation, a first read voltage to a first page of memory cells, wherein the first read voltage is in accordance with a first offset applied to a read voltage;
apply, in accordance with the read operation, a second read voltage to a second page of memory cells in accordance with applying the first read voltage, wherein the second read voltage is in accordance with a second offset applied to the read voltage; and
adjust the read voltage based on a first quantity of bit errors associated with the first page of memory cells being different from a second quantity of bit errors associated with the second page of memory cells.

2. The memory system of claim 1, wherein the processing circuitry is further configured to cause the memory system to:
apply the adjusted read voltage to a third page of memory cells in accordance with adjusting the read voltage, wherein the read operation comprises a sequential read operation.

3. The memory system of claim 1, wherein the processing circuitry is further configured to cause the memory system to:
store an indication of the adjustment made to the read voltage in accordance with adjusting the read voltage; and
apply, in accordance with a random read operation, the adjusted read voltage to a fourth page of memory cells in accordance with storing the indication of the adjustment made to the read voltage.

4. The memory system of claim 1, wherein the processing circuitry is further configured to cause the memory system to:
determine the first quantity of bit errors associated with the first page of memory cells and the second quantity of bit errors associated with the second page of memory cells;
store the first quantity of bit errors and the second quantity of bit errors to the memory system after determining the first quantity of bit errors and the second quantity of bit errors; and
compare the first quantity of bit errors to the second quantity of bit errors after storing the second quantity of bit errors to the memory system, wherein adjusting the read voltage is based on comparing the first quantity of bit errors to the second quantity of bit errors.

5. The memory system of claim 4, wherein the processing circuitry is further configured to cause the memory system to:
determine that the first quantity of bit errors is greater than the second quantity of bit errors, wherein adjusting the read voltage comprises decreasing the read voltage based on the first quantity of bit errors being greater than the second quantity of bit errors.

6. The memory system of claim 4, wherein the processing circuitry is further configured to cause the memory system to:
determine that the first quantity of bit errors is less than the second quantity of bit errors, wherein adjusting the read voltage comprises increasing the read voltage based on the first quantity of bit errors being less than the second quantity of bit errors.

7. The memory system of claim 4, wherein the processing circuitry is further configured to cause the memory system to:
determine that the first quantity of bit errors is equal to the second quantity of bit errors; and
refrain from adjusting the read voltage based on the first quantity of bit errors being equal to the second quantity of bit errors.

8. The memory system of claim 4, wherein the processing circuitry is further configured to cause the memory system to:
decode a first codeword associated with the first page, wherein determining the first quantity of bit errors is in accordance with decoding the first codeword; and
decode a second codeword associated with the second page, wherein determining the second quantity of bit errors is in accordance with decoding the second codeword.

9. The memory system of claim 1, wherein the processing circuitry is further configured to cause the memory system to:
apply the first read voltage to a fifth page of a second block of memory cells;
determine that a third quantity of bit errors associated with the fifth page does not satisfy a threshold value; and
refrain from adjusting the read voltage for the second block based on determining that the third quantity of bit errors does not satisfy the threshold value.

10. The memory system of claim 1, wherein the processing circuitry is further configured to cause the memory system to:
receive a command for reading data from a block of memory cells, the block comprising at least the first page and the second page, wherein applying the first read voltage and applying the second read voltage is based on receiving the command.

11. The memory system of claim 10, wherein the processing circuitry is further configured to cause the memory system to:
apply the first offset to the read voltage before applying the first read voltage to the first page of memory cells, wherein applying the first offset to the read voltage comprises increasing the read voltage by a voltage value; and
apply the second offset to the read voltage before applying the second read voltage to the second page of memory cells, wherein applying the second offset to the read voltage comprises decreasing the read voltage by the voltage value.

12. The memory system of claim 1, wherein the processing circuitry is further configured to cause the memory system to:
receive a command for reading second data from a third block of memory cells, the third block comprising at least a sixth page; and
refrain from determining a fourth quantity of bit errors associated with the sixth page based on being unable to decode a third codeword associated with the sixth page.

13. The memory system of claim 12, wherein the processing circuitry is further configured to cause the memory system to:
correct one or more errors associated with the sixth page in accordance with being unable to decode the third codeword associated with the sixth page.

14. A memory system, comprising:
one or more memory devices; and
processing circuitry coupled with the one or more memory devices and configured to cause the memory system to:
apply, in accordance with a read operation, a first read voltage to a first page of memory cells;
issue an internal command in response to a first quantity of bit errors associated with the first page of memory cells satisfying a threshold value; and
read a second page of memory cells using an adjusted read voltage that is based on issuing the internal command and based on an offset between the first read voltage and a target read voltage.

15. The memory system of claim 14, wherein applying the first read voltage to the first page of memory cells results in the first quantity of bit errors, and the processing circuitry is further configured to cause the memory system to:
apply a second read voltage to the first page of memory cells, wherein applying the second read voltage to the first page of memory cells results in a second quantity of bit errors; and
determine that the first quantity of bit errors satisfies the threshold value based on applying the first read voltage and the second read voltage.

16. The memory system of claim 15, wherein the processing circuitry is further configured to cause the memory system to:
calculate a slope associated with the first quantity of bit errors and the second quantity of bit errors, wherein the adjustment to the read voltage is based on calculating the slope.

17. The memory system of claim 14, wherein the first page and the second page are sequential pages of a block of memory cells.

18. A method by a memory system, comprising:
applying, in accordance with a read operation, a first read voltage to a first page of memory cells, wherein the first read voltage is in accordance with a first offset applied to a read voltage;
applying, in accordance with the read operation, a second read voltage to a second page of memory cells in accordance with applying the first read voltage, wherein the second read voltage is in accordance with a second offset applied to the read voltage; and
adjusting the read voltage based on a first quantity of bit errors associated with the first page of memory cells being different from a second quantity of bit errors associated with the second page of memory cells.

19. The method of claim 18, further comprising:
applying the adjusted read voltage to a third page of memory cells in accordance with adjusting the read voltage, wherein the read operation comprises a sequential read operation.

20. The method of claim 18, further comprising:
storing an indication of the adjustment made to the read voltage in accordance with adjusting the read voltage; and
applying, in accordance with a random read operation, the adjusted read voltage to a fourth page of memory cells in accordance with storing the indication of the adjustment made to the read voltage.

21. The method of claim 18, further comprising:
determining the first quantity of bit errors associated with the first page of memory cells and the second quantity of bit errors associated with the second page of memory cells;
storing the first quantity of bit errors and the second quantity of bit errors to the memory system after determining the first quantity of bit errors and the second quantity of bit errors; and
comparing the first quantity of bit errors to the second quantity of bit errors after storing the second quantity of bit errors to the memory system, wherein adjusting the read voltage is based on comparing the first quantity of bit errors to the second quantity of bit errors.

22. The method of claim 21, further comprising:
determining that the first quantity of bit errors is greater than the second quantity of bit errors, wherein adjusting the read voltage comprises decreasing the read voltage based on the first quantity of bit errors being greater than the second quantity of bit errors.

23. The method of claim 21, further comprising:
determining that the first quantity of bit errors is less than the second quantity of bit errors, wherein adjusting the read voltage comprises increasing the read voltage based on the first quantity of bit errors being less than the second quantity of bit errors.
